(19) United States
(12) Patent Application Publication
(10) Pub. No.: US 2008/0003815 A1
(43) Pub. Date: Jan. 3, 2008

(54) METHOD OF FORMING A BARRIER METAL LAYER OF A SEMICONDUCTOR DEVICE

(75) Inventors: Hyun-Suk LEE, Gyeonggi-do (KR); Hyun-Seok LIM, Gyeonggi-do (KR); Rak-Hwan KIM, Gyeonggi-do (KR); In-Sun PARK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/770,619

(22) Filed: Jun. 28, 2007

(30) Foreign Application Priority Data
Jun. 28, 2006 (KR) 2006-58960

(51) Int. Cl. H01L 21/44

(52) U.S. Cl. 438/653; 257/E21.476

(57) ABSTRACT

Provided is a method of forming a barrier metal layer of a semiconductor device. In the method, a barrier metal layer is formed on a top surface of a semiconductor substrate and then an electrode layer is formed on the semiconductor substrate. Forming the barrier metal layer includes performing a cyclic process repeatedly at least twice. The cyclic process includes depositing a titanium layer and nitriding the deposited titanium layer.

### CROSS-REFERENCE TO RELATED APPLICATIONS

This U.S. non-provisional patent application claims priority under 35 U.S.C. §119 of Korean Patent Application No. 2006-58960, filed on Jun. 28, 2006, the entire contents of which are hereby incorporated by reference.

### BACKGROUND

The present invention disclosed herein relates to a method of fabricating a semiconductor device, and more particularly, to a method of forming a barrier metal layer of a semiconductor device.

With the development of electronic industries such as mobile communications and computers, semiconductor devices are generally required to have high read/write speeds, nonvolatility, and a low operating voltage. However, none of the existing memory devices, such as a static random access memory (SRAM), a dynamic random access memory (DRAM), and a flash memory succeeds in providing all of these characteristics.

Comparing the various memory types, DRAM has a larger unit cell area than that of NAND flash memory because its unit cell includes one capacitor and one transistor for controlling the capacitor. In addition, DRAM is a volatile memory device requiring a refresh operation because it stores data in the capacitor. SRAM has a high operating speed but is also a volatile memory device. The SRAM also has a very large unit cell area because its unit cell includes six transistors. The NAND flash memory is a nonvolatile memory device and provides the highest integration level among the existing memory devices, but it suffers from a low operating speed.

Accordingly, active research is directed to providing memory devices that have high read/write speeds, nonvolatility, and a low operating voltage, while not requiring a refresh operation.

A phase-change random access memory (PRAM) is one of the next-generation memory devices that are expected to satisfy such technical requirements. For example, the PRAM can provide a high operating speed of about 30 ns. It also has a long lifetime, being able to provide about at least 1013 rewrite operations.

FIG. 1 is a cross-sectional view of a conventional PRAM.

Referring to FIG. 1, the conventional PRAM has a phase-change pattern 40 disposed on an electrical path connecting a source line 70 and a bit line 50. The conventional PRAM detects stored data by sensing a resistance change depending on the crystalline state of the phase-change pattern 40. The crystalline state of the phase-change pattern 40 can be changed by controlling a current flowing therethrough. To control and sense the current, the conventional PRAM has a transistor disposed on a semiconductor substrate 10.

The transistor includes a gate electrode 20 disposed on the semiconductor substrate 10 and source/drain regions 30 disposed on both sides of the gate electrode 20. The source/drain regions 30 are connected respectively to the phase-change pattern 40 using a contact plug 64 and the source line 70.

Consequently, a unit cell of the conventional PRAM includes one transistor disposed on the semiconductor substrate 10 and one phase-change pattern 40 disposed at one side of the transistor. Therefore, the conventional PRAM is similar in unit cell area to the DRAM, as described above. As a result, the conventional PRAM has excellent characteristics that meet the requirements for a next-generation memory. But the PRAM is difficult to integrate more highly than the DRAM. To overcome this integration limit, a PRAM has been proposed, which uses a diode capable of interrupting a reverse current. This diode replaces the role of the transistor in FIG. 1.

FIG. 2 is a flowchart illustrating a method of fabricating a conventional diode-based PRAM.

Referring to FIG. 2, a PN junction pattern constituting a diode is formed on a semiconductor substrate (step S 10), and a memory structure connected to the PN junction pattern is formed. Forming the memory structure includes forming a bottom electrode on the PN junction pattern (step S20) and sequentially forming a phase-change layer, a top electrode, and a bit line on the bottom electrode (step S30).

The bottom electrode is used as a heater for changing the crystalline state of the phase-change layer. Therefore, the bottom electrode is formed of a high-resistivity conductive material such as TiAlN. However, a desired heating location is specifically the top portion of the bottom electrode contacting the phase-change layer. Therefore, a contact resistance between the bottom electrode and the PN junction pattern should be reduced in order to reduce the power consumption of the diode-based PRAM. To reduce the contact resistance, a silicide layer or a barrier metal layer may be formed before forming the bottom electrode.

In an embodiment of the conventional art, a cobalt silicide layer is used as the silicide layer and a titanium layer deposited by CVD is used as the barrier metal layer. If only the silicide layer is formed without forming the barrier metal layer, then the contact resistance between the bottom electrode and the PN junction pattern is difficult to reduce. On the contrary, when both the barrier metal layer and the silicide layer are formed, the contact resistance can be reduced. However, when the barrier metal layer is formed, titanium atoms contained in the barrier metal layer may diffuse into the phase-change layer to create an electrical path that connects the phase-change layer and the PN junction pattern. This results in an increased reset current of the diode-based PRAM, which may cause difficulty in discriminating between the PRAM's on state and off state.

### SUMMARY

The present invention includes embodiments that provide a method of minimizing a contact resistance of a semiconductor device.

The present invention also provides method embodiments of fabricating a semiconductor device for reducing a contact resistance between a bottom electrode and a PN junction pattern of a PRAM. Embodiments also include a method of fabricating a semiconductor device that can minimize diffusion of metal atoms contained in a barrier metal layer of a PRAM into a phase-change layer.

Embodiments provide methods of forming a barrier metal layer of a semiconductor device, the methods including forming a cyclic titanium layer between a silicon layer and a bottom electrode. The methods include forming a barrier metal layer on a top surface of a substrate, and forming an electrode layer on the semiconductor substrate. Forming the barrier metal layer may include performing a cyclic process repeatedly. The cyclic process may include depositing a titanium layer and nitriding the deposited titanium layer.

In some embodiments, depositing the titanium layer is performed using TiCl₄ gas as a source gas and nitriding the deposited titanium layer is performed using a process gas containing NH₃ or N₂. In other embodiments, the methods further include performing an RTN process on the resulting structure including the barrier metal layer before forming the electrode layer. In addition, forming the barrier metal layer further includes performing a purge process after depositing the titanium layer and another purge process after nitriding the deposited titanium layer.

In other embodiments, the methods further include, before forming the barrier metal layer, forming a PN junction pattern on the semiconductor substrate; forming a silicide pattern on the PN junction pattern; and forming a spacer on the silicide pattern. In this case, the electrode layer is formed of a TiAlN layer. The TiAlN layer is used as a bottom electrode of a PRAM device, and the barrier metal layer contributes to reducing a contact resistance between the electrode layer and the PN junction pattern.

In still other embodiments, the methods further include sequentially forming a phase-change layer, a top electrode layer, and a metal layer on the electrode layer. In this case, the nitriding of the deposited titanium layer can prevent diffusion of titanium atoms contained in the deposited titanium layer into the phase-change layer.

In still other embodiments, the methods further include performing an RTN process on the resulting structure including the electrode layer before forming the phase-change layer.

In yet other embodiments, methods of forming a barrier metal layer of a semiconductor device include forming a cyclic titanium layer between a PN junction pattern and a bottom electrode. The methods include forming a PN junction pattern on a semiconductor substrate, forming a silicide pattern on the PN junction pattern, forming a spacer on the silicide pattern, forming a barrier metal layer on the resulting structure including the spacer, forming a bottom electrode filling the internal space of the spacer on the resulting structure including the barrier metal layer, and sequentially forming a phase-change layer, a top electrode layer, and a metal layer on the bottom electrode. Forming the barrier metal layer includes performing a cyclic process repeatedly, the cyclic process including depositing a titanium layer and nitriding the deposited titanium layer.

In some embodiments, the methods further include performing an RTN process on the resulting structure including the barrier metal layer before forming the bottom electrode. In addition, the methods further include performing an RTN process on the resulting structure including the bottom electrode before forming the phase-change layer.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain its principles. In the figures:

FIG. 1 is a cross-sectional view of a conventional PRAM;

FIG. 2 is a flowchart illustrating a method of fabricating a conventional diode-based PRAM;

FIG. 3 is a flowchart illustrating a method of fabricating a semiconductor device according to an embodiment;

FIGS. 4A through 4H are perspective views illustrating a method of fabricating semiconductor device according to the embodiment;

FIG. 5 is a timing diagram of gas supply for forming a cyclic titanium layer according to the embodiment; and

FIG. 6 is a graph illustrating some characteristics of a cyclic titanium layer, comparing that of the embodiment with that of the conventional art.

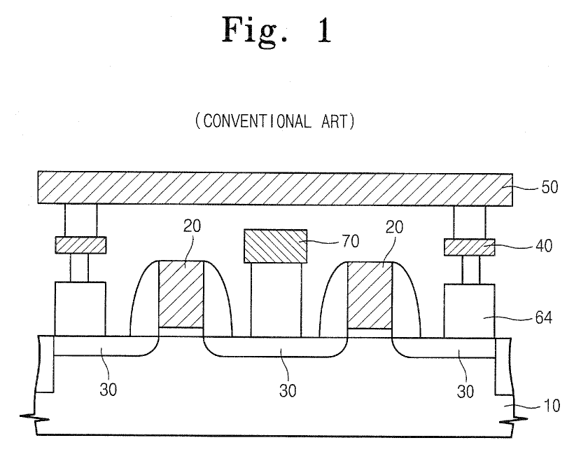

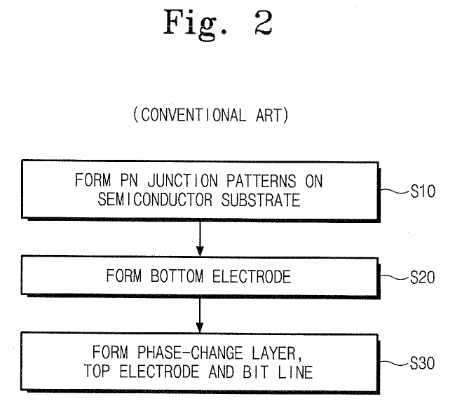

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the specification, the dimensions of layers and regions are exaggerated for clarity of illustration. It will also be understood that when a layer (or film) is referred to as being ‘on’ another layer or substrate, it can be directly on the other layer or substrate, or intervening layers may also be present. Also, though terms like a first, a second, and a third are used to describe various regions and layers in various embodiments of the present invention, the regions and the layers are not limited to these terms. These terms are used only to tell one region or layer from another region or layer. Therefore, a layer referred to as a first layer in one embodiment can be referred to as a second layer in another embodiment. An embodiment described and exemplified herein includes a complementary embodiment thereof.

Hereinafter, an exemplary embodiment will be described in conjunction with the accompanying drawings.

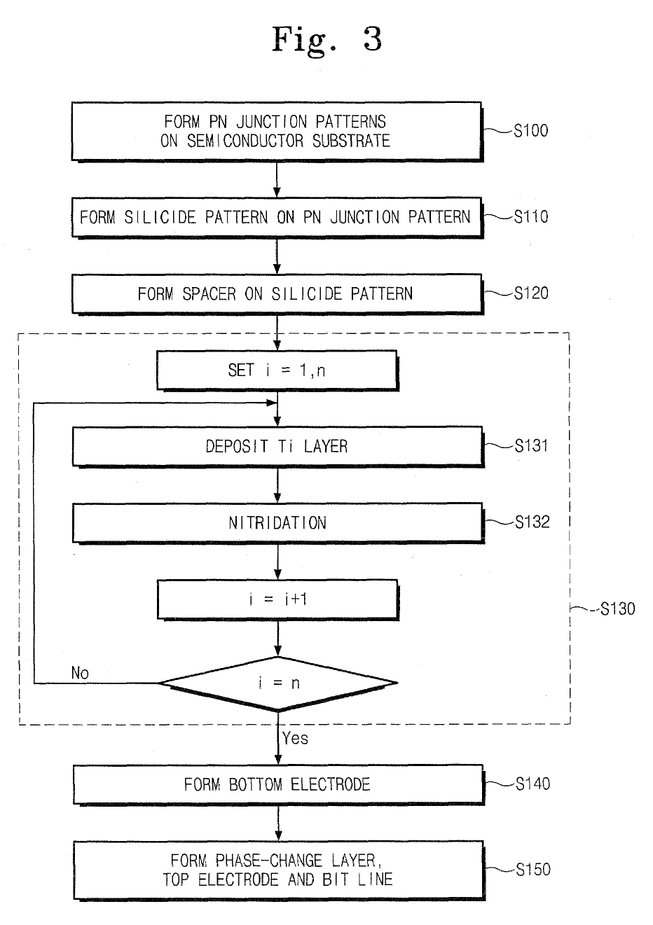

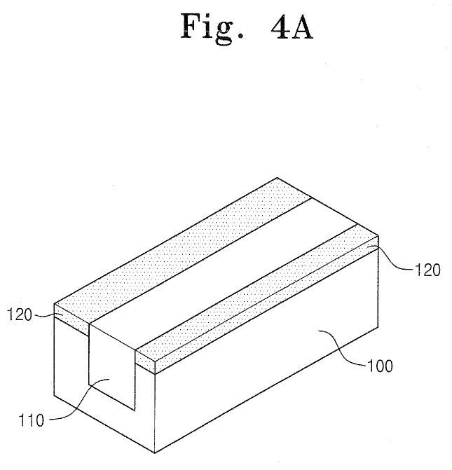

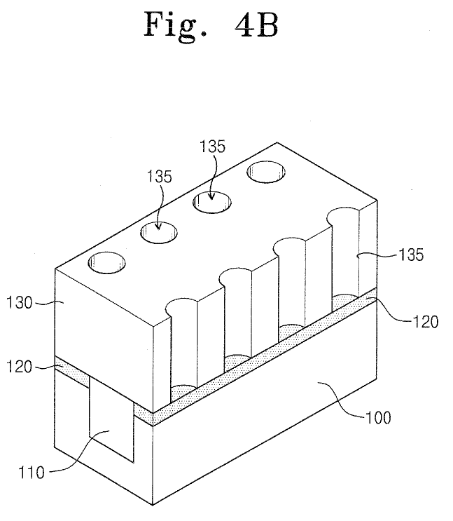

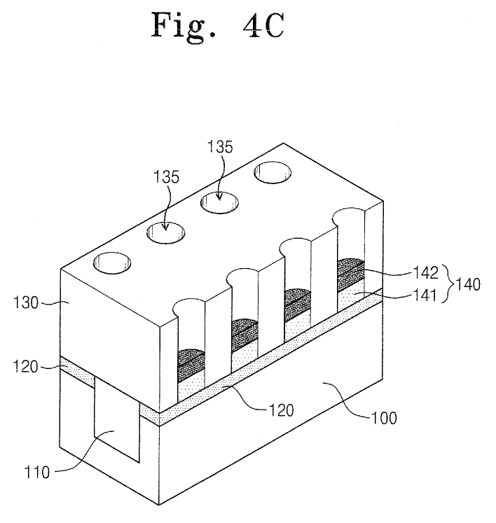

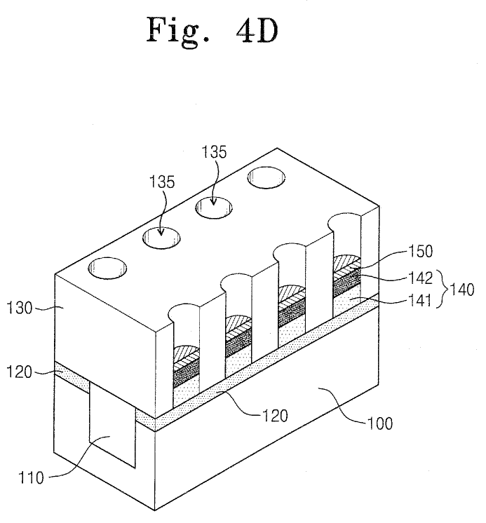

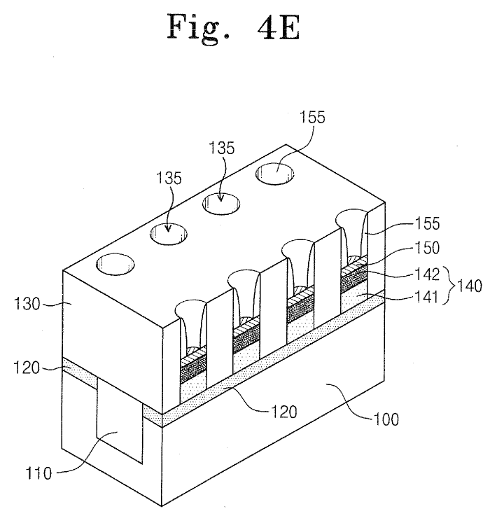

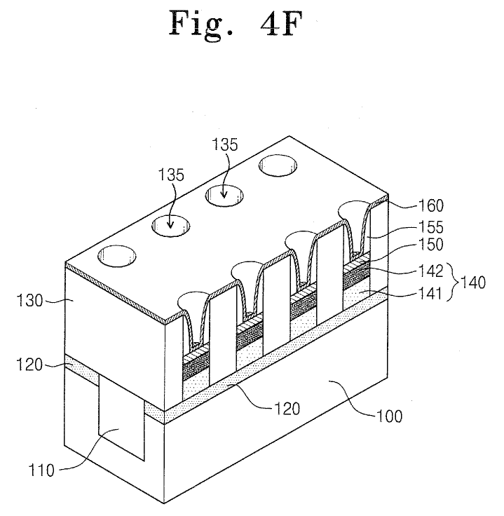

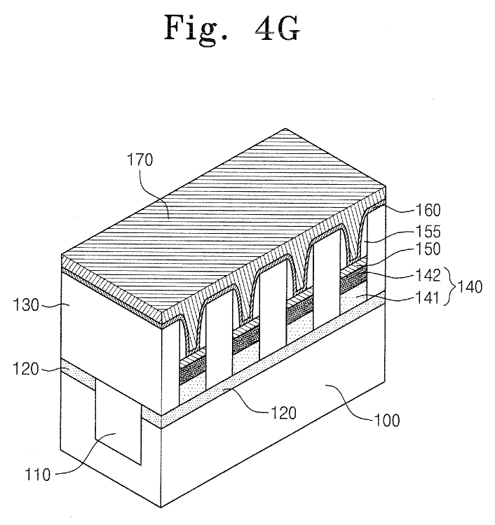

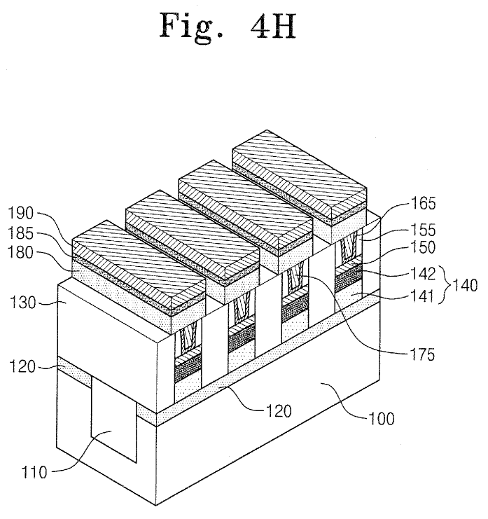

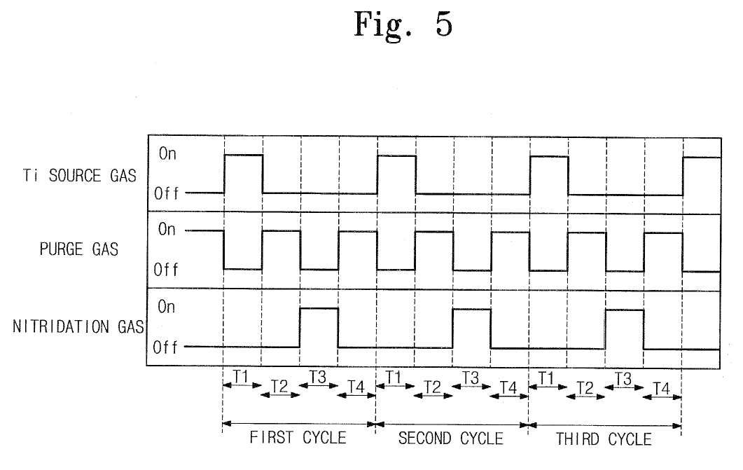

FIG. 3 is a flowchart illustrating a method of fabricating a semiconductor device according to an embodiment. FIGS. 4A through 4H are perspective views illustrating a method of fabricating a semiconductor device according to the embodiment. FIG. 5 is a timing diagram of a gas supply for forming a cyclic titanium layer according to the embodiment.

Referring to FIG. 4A, device isolation layer patterns 110 defining an active region are formed in a predetermined region of a semiconductor substrate 100. The device isolation layer patterns may be formed using a shallow trench isolation (STI) method. A conductive region 120 may then be formed on the active region.

In an embodiment, the conductive region 120 is used as a line that connects memory cells of a PRAM in a predetermined direction. To this end, the conductive region 120 may contain high-concentration impurities having a different conductivity type than the semiconductor substrate 100. For example, the conductive region 120 may be an n⁺ impurity region.

In another embodiment, a conductive pattern of a metallic material may be formed to replace the conductive region 120. This embodiment is disclosed in U.S. patent application Ser. No. 11/600,719 and thus its description will be omitted for conciseness.

Referring to FIG. 4B, an interlayer insulating layer 130 may be formed on the resulting structure including the conductive region 120. The interlayer insulating layer 130 may be formed of a silicon oxide layer and may further include an insulating layer such as a silicon nitride layer and a silicon oxide nitride layer.

Thereafter, the interlayer insulating layer 130 may be patterned to form openings 135 that expose the conductive region 120. The openings 135 define a region for a memory structure of a PRAM according to the present embodiment. Forming the openings 135 may include etching the interlayer insulating layer 130 anisotropically by an etch recipe having an etch selectivity with respect to a silicon layer.

To achieve the above etch selectivity, the interlayer insulating layer 130 may be formed of a silicon nitride layer and a silicon oxide layer that are stacked sequentially. In this case, the forming of the openings 135 may include etching a silicon oxide layer by an etch recipe having an etch selectivity with respect to a silicon nitride layer and etching a silicon nitride layer by an etch recipe having an etch selectivity with respect to a silicon layer.

Referring now to FIG. 4C, a PN junction pattern 140 may be formed in a bottom region of the opening 135 (step S100 in FIG. 3). The PN junction pattern 140 constitutes a diode that may be used for selective access to the memory cells of the PRAM. When the conductive region 120 contains high-concentration n-type (i.e., n⁺) impurities as stated above, the PN junction pattern 140 may be formed of an n⁻ impurity layer 141 and a p⁺ impurity region 142 that are stacked sequentially.

Forming the PN junction pattern 140 may include performing an epitaxial process using the exposed semiconductor layer 100 (specifically, the conductive region 120) as a seed layer. In an embodiment, an epitaxial layer grown by the epitaxial process may be formed to fill the opening 135 and is then etched back until the sidewalls of the opening 135 are exposed. Thereafter, a predetermined ion implantation process may be performed to form the n⁻ impurity layer 141 and the p⁺ impurity layer 142. Meanwhile, the PN junction pattern 140 may be formed using a variety of other known methods. For example, the n⁻ impurity layer 141 and the p⁺ impurity layer 142 may be respectively formed by implanting n-type impurities and p-type impurities during the epitaxial process.

Referring to FIGS. 4D and 4E, a silicide pattern 150 may be formed on the PN junction pattern 140 (step S 110 in FIG. 3). And then a spacer 155 covering the inner wall of the opening 135 may be formed on the silicide pattern 150 (step s120 in FIG. 3).

The silicide pattern 150 may be formed of silicide materials, such as cobalt silicide or tungsten silicide. Forming the silicide pattern 150 may include forming a metal (e.g., cobalt and tungsten) layer on the resulting structure including the PN junction pattern 140 and performing a self-aligned silicidation process. By the self-aligned silicidation process, the silicide pattern 150 may be selectively formed on the PN junction pattern 140.

The spacer 155 may be formed of an insulating material layer such as a silicon oxide layer or a silicon nitride layer. According to the present embodiment, a bottom electrode of the PRAM may be formed in a top region of the opening 135 that is surrounded by the spacer 155. As is well known in the art, the electrical resistance of the bottom electrode is preferably increased to reduce the power consumption of the PRAM, and the spacer 155 is formed to reduce the electrical resistance of the bottom electrode. That is, the spacer 155 is formed to reduce the width of the top region of the opening 135, thereby increasing the electrical resistance of the bottom electrode formed in the top region of the opening 135. With the inclusion of the spacer 155 in the opening 135, an inner space is formed inside the spacer. The thickness of the spacer 155 on the wall of the opening 135 may be greater in a bottom portion than in a top portion. so that a radius in a bottom portion of the inner space is less than a radius in a top portion of the inner space.

Referring to FIG. 4F, a barrier metal layer 160 may be formed on the resulting structure including the spacer 155 (step 130 in FIG. 3). According to the present embodiment, the barrier metal layer 160 may be a cyclic titanium layer that is formed by performing deposition and nitridation repeatedly.

More specifically, referring to FIGS. 3 and 5, the cyclic titanium layer may be formed by performing a cycle of first through fourth processes T1 through T4 repeatedly at least twice (i.e., n=2 in FIG. 3). In an embodiment of the present embodiment, the first process T1 may be a process of depositing a titanium layer using TiCl₄ as a source gas (step S131 in FIG. 3), the third process T3 may be a process of exposing the deposited titanium layer to a nitridation gas such as ammonia (NH₃) gas (step 132 in FIG. 3), and the second and fourth processes T2 and T4 may be processes of purging the source gas and the nitridation gas from the process chamber where the cycles take place. In another embodiment, a process gas containing nitrogen instead of the ammonia gas may be used as the nitridation gas. In addition, inert gases such as nitrogen may be used as a purge gas for the purge processes T2 and R4.

By repetition of the deposition/nitridation processes, a titanium nitride layer may be formed on the deposited titanium layer. The titanium nitride layer prevents diffusion of titanium atoms contained in a titanium layer formed in each deposition process. Accordingly, it is possible to prevent the diffusion of titanium atoms into the phase-change layer and the consequent increase of the reset current of the PRAM, which are the problems of the conventional art.

Meanwhile, in another embodiment, after forming the barrier metal layer 160, a rapid thermal nitridation (RTN) process may be additionally performed on the resulting structure including the barrier metal layer 160. This RTN process also contributes to the prevention of the diffusion of the titanium atoms contained in the barrier metal layer 160.

Referring to FIG. 4G, a bottom electrode layer 170 may be formed on the resulting structure including the barrier metal layer 160.

In an embodiment, the bottom electrode layer 170 may be a TiAlN layer. Forming the TiAlN layer may include supplying a process gas such as TiCl₄, tetra-methyl-aluminum (TMA), and ammonia (NH₃) into a process chamber that is heated to 450˜500° C., for example. In another embodiment, the bottom electrode layer 170 may be formed in the same process chamber that is used to form the barrier metal layer 160.

Referring to FIG. 4H, the bottom electrode layer 170 and the barrier metal layer 160 may be sequentially etched until the interlayer insulating layer 130 is exposed, thereby forming a bottom electrode 175 and a barrier metal pattern 165 in the top region of the opening 135. This process may be performed using a chemical mechanical polishing (CMP) process, for example.

Thereafter, a phase-change layer, a top electrode layer, and a metal layer may be sequentially formed on the resulting structure that includes the bottom electrode 175. These layers may then be patterned to form a phase-change layer pattern 180, a top electrode 185, and a bit line 190 that connect to the bottom electrodes 175. According to the present embodiment, the bit line 190 may be formed across the conductive region 120.

The phase-change layer may be formed of one selected from alloys containing antimony (Sb). For example, the phase-change layer may be formed of Ge₂Sb₂Te₅ (hereinafter referred to as a GTS layer). As described above, the phase-change layer exhibits variable resistance characteristics depending on its crystalline state, which may be used to determine data stored in a memory cell of the PRAM.

In another embodiment, the phase-change layer pattern 180, the top electrode 185, and the bit line 190 may be formed using other known techniques such as a damascene process.

In another embodiment, before forming the phase-change layer, an RTN process may be additionally performed on the resulting structure including the bottom electrode 175 and the barrier metal pattern 165. This RTN process also contributes to the prevention of the diffusion of the titanium atoms contained in the barrier metal pattern 165. In light of the fact that the non-nitrided section of the titanium layer can be exposed by the CMP process, it is preferable that an RTN process is performed on the resulting structure including the barrier metal pattern 165 before forming the phase-change layer. Accordingly, it is possible to prevent the diffusion of titanium atoms into the phase-change layer pattern 180 and the consequent increase of the reset current of the PRAM, which are the problems of the conventional art.

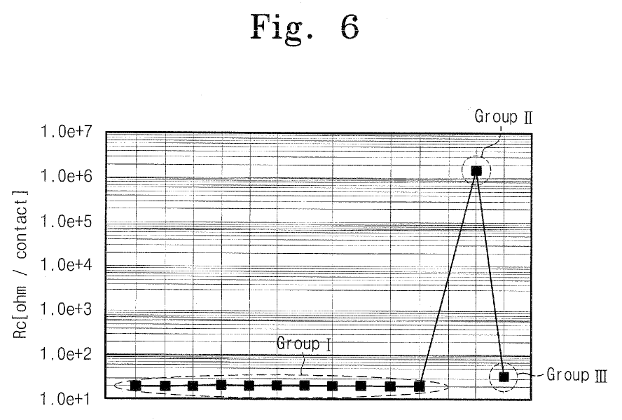

FIG. 6 is a graph illustrating and comparing some characteristics of a cyclic titanium layer according to an example of the present embodiment and the conventional art.

Referring to FIG. 6, Group I denotes the contact resistance of a memory device where a cobalt silicide layer and a CVD Ti layer are formed between a PN junction pattern and a bottom electrode. Group II denotes the contact resistance of a memory device where only a cobalt silicide layer is formed between a PN junction pattern and a bottom electrode And Group III denotes the contact resistance of a memory device where a cobalt silicide layer and a cyclic titanium layer are sequentially formed between a PN junction pattern and a bottom electrode. IN this example, the cyclic titanium layer for Group III is formed to a thickness of about 74 Å using the method illustrated with reference to FIG. 4F. Consequently, the contact resistance of the memory device according to the present embodiment corresponds to Group III, while those of the conventional art correspond to Group I and Group II.

As can be seen from FIG. 6, the contact resistance of Group II without the barrier metal layer is much higher than the contact resistances of Groups I and III that have the barrier metal layer. Consequently, it can be seen that the barrier metal layer reduces the contact resistance. It can also be seen that the cyclic titanium layer according to the present embodiment can provide the same technical effect as the conventional CVD Ti layer in terms of the reduction of the contact resistance. However, while the conventional CVD Ti layer causes the diffusion of titanium atoms into the phase-change layer and the consequent increase of the reset current of the PRAM, the cyclic titanium layer according to the present embodiment is free from such conventional problems.

As described above, the embodiment repeatedly performs the deposition of the titanium layer and the nitridation of the deposited titanium layer, thereby forming the cyclic titanium layer between the silicon layer (e.g., the PN junction pattern) and the bottom electrode. Accordingly, the contact resistance between the silicon layer and the bottom electrode can be reduced. In addition, the repetition of the nitridation of the deposited titanium layer can minimize the diffusion of the titanium atoms of the deposited titanium layer into the phase-change layer, thus contributing to preventing an increase in the reset current of the PRAM.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of forming a barrier metal layer of a semiconductor device, the method comprising:
preparing a semiconductor substrate;
forming a barrier metal layer on a top surface of the semiconductor substrate; and
forming an electrode layer on the semiconductor substrate,
wherein forming the barrier metal layer comprises performing a cyclic process repeatedly at least two times, the cyclic process including depositing a titanium layer and nitriding the deposited titanium layer.

2. The method of claim 1, wherein depositing the titanium layer is performed using TiCl₄ gas as a source gas and nitriding the deposited titanium layer is performed using a process gas containing NH₃ gas or N₂ gas.

3. The method of claim 1, further comprising performing a rapid thermal nitridation (RTN) process on the resulting structure that includes the barrier metal layer before forming the electrode layer.

4. The method of claim 1, wherein forming the barrier metal layer further comprises performing a purge process after depositing the titanium layer and another purge process after nitriding the deposited titanium layer.

5. The method of claim 1, further comprising, before forming the barrier metal layer:
forming a PN junction pattern on the semiconductor substrate;
forming a silicide pattern on the PN junction pattern; and
forming a spacer on the silicide pattern.

6. The method of claim 5, wherein the electrode layer is formed of a TiAlN layer that is used as a bottom electrode of a PRAM device.

7. The method of claim 5, further comprising reducing a contact resistance between the electrode layer and the PN junction pattern by using the barrier metal layer.

8. The method of claim 5, further comprising sequentially forming a phase-change layer, a top electrode layer, and a metal layer on the electrode layer, and
preventing diffusion of titanium atoms contained in the deposited titanium layer into the phase-change layer by using the nitrided titanium layer.

9. The method of claim 8, further comprising performing a rapid thermal nitridation (RTN) process on the resulting structure including the electrode layer before forming the phase-change layer.

10. A method of forming a barrier metal layer of a semiconductor device, the method comprising:
forming a PN junction pattern on a semiconductor substrate;
forming a silicide pattern on the PN junction pattern;
forming a spacer on the silicide pattern, the spacer defining an inner space;
forming a barrier metal layer on the resulting structure including the spacer;
forming a bottom electrode to fill the inner space defined by the spacer on the resulting structure including the barrier metal layer; and
sequentially forming a phase-change layer, a top electrode layer, and a metal layer on the bottom electrode,
wherein forming the barrier metal layer comprises performing a cyclic process repeatedly at least two times, the cyclic process including depositing a titanium layer and nitriding the deposited titanium layer.

11. The method of claim 10, wherein depositing the titanium layer is performed using TiCl₄ gas as a source gas and the nitriding of the deposited titanium layer is performed using a process gas containing NH₃ gas or N₂ gas.

12. The method of claim 10, further comprising performing a rapid thermal nitridation (RTN) process on the resulting structure including the barrier metal layer before forming the bottom electrode.

13. The method of claim 10, wherein forming the barrier metal layer further comprises performing a purge process after depositing the titanium layer and another purge process after nitriding the deposited titanium layer.

14. The method of claim 10, wherein the bottom electrode is formed of a TiAlN layer.

15. The method of claim 10, further comprising reducing a contact resistance between the bottom electrode and the PN junction pattern by using the barrier metal layer.

16. The method of claim 10, further comprising performing a rapid thermal nitridation (RTN) process on the resulting structure including the bottom electrode before forming the phase-change layer.

17. The method of claim 10, further comprising preventing diffusion of the deposited titanium layer into the phase-change layer by using the nitrided titanium layer.

18. The method of claim 10, further comprising, before forming the PN junction pattern, forming openings in an interlayer insulating layer disposed on the semiconductor substrate to include the PN junction within the openings.

19. A method of forming a barrier metal layer of a semiconductor device, the method comprising:
forming an interlayer insulating layer on a semiconductor substrate;
forming an opening in the interlayer insulating layer;
forming a PN junction in the opening;
forming a silicide layer on the PN junction;
forming a spacer on the silicide layer, the spacer defining an inner space;
forming a barrier metal layer on the resulting structure including the spacer;
forming a bottom electrode to fill the inner space defined by the spacer on the resulting structure including the barrier metal layer; and
sequentially forming a phase-change layer, a top electrode layer, and a metal layer on the bottom electrode,
wherein forming the barrier metal layer comprises performing a cyclic process repeatedly at least two times, the cyclic process including depositing a titanium layer and nitriding the deposited titanium layer.

20. The method of claim 19, wherein a radius in a bottom portion of the inner space is less than a radius in a top portion of the inner space.
